(19) United States
(12) Patent Application Publication
(10) Pub. No.: US 2010/0282307 A1
(43) Pub. Date: Nov. 11, 2010

(54) Multijunction Solar Cells with Group IV/III-V Hybrid Alloys for Terrestrial Applications

(75) Inventors: Paul Sharps, Albuquerque, NM (US); Fred Newman, Albuquerque, MN (US)

Correspondence Address: EMCORE CORPORATION, 1600 EUBANK BLVD, S.E., ALBUQUERQUE, NM, 87123, US

(73) Assignee: Emcore Solar Power, Inc., Albuquerque, MN (US)

(21) Appl. No.: 12/463,226

(22) Filed: May 8, 2009

(51) Int. Cl. H01L 31/00

(52) U.S. Cl. 136/255

(57) ABSTRACT

A solar cell including a substrate; a first solar subcell composed of GeSiSn disposed over the substrate and having a first band gap; a second solar subcell composed of GaAs, InGaAsP, or InGaP and disposed over the first solar subcell having a second band gap greater than the first band gap and lattice matched to said first solar subcell; and a third solar subcell composed of GaInP and disposed over the second solar subcell having a third band gap greater than the second band gap and lattice matched with respect to the second subcell.

### REFERENCE TO RELATED APPLICATIONS

This application is related to co-pending U.S. patent application Ser. No. ______ and Ser. No. ______, filed ______, 2009.

### BACKGROUND OF THE INVENTION

1. Field of the Invention

The present invention relates to the field of semiconductor devices, and to fabrication processes and devices such as multifunction solar cells based on Group IV/III-V hybrid semiconductor compounds.

2. Description of the Related Art

Solar power from photovoltaic cells, also called solar cells, has been predominantly provided by silicon semiconductor technology. In the past several years, however, high-volume manufacturing of III-V compound semiconductor multijunction solar cells for space applications has accelerated the development of such technology not only for use in space but also for terrestrial solar power applications. Compared to silicon, III-V compound semiconductor multifunction devices have greater energy conversion efficiencies and generally more radiation resistance, although they tend to be more complex to manufacture. Typical commercial III-V compound semiconductor multijunction solar cells have energy efficiencies that exceed 27% under one sun, air mass 0 (AM0), illumination, whereas even the most efficient silicon technologies generally reach only about 18% efficiency under comparable conditions. Under high solar concentration (e.g., 500×), commercially available III-V compound semiconductor multifunction solar cells in terrestrial applications (at AM1.5D) have energy efficiencies that exceed 37%. The higher conversion efficiency of III-V compound semiconductor solar cells compared to silicon solar cells is in part based on the ability to achieve spectral splitting of the incident radiation through the use of a plurality of photovoltaic regions with different band gap energies, and accumulating the current from each of the regions.

In satellite and other space related applications, the size, mass and cost of a satellite power system are dependent on the power and energy conversion efficiency of the solar cells used. Putting it another way, the size of the payload and the availability of on-board services are proportional to the amount of power provided. Thus, as payloads become more sophisticated, the power-to-weight ratio of a solar cell becomes increasingly more important, and there is increasing interest in lighter weight, “thin film” type solar cells having both high efficiency and low mass.

Typical III-V compound semiconductor solar cells are fabricated on a semiconductor wafer in vertical, multifunction structures. The individual solar cells or wafers are then disposed in horizontal arrays, with the individual solar cells connected together in an electrical series circuit. The shape and structure of an array, as well as the number of cells it contains, are determined in part by the desired output voltage and current.

### SUMMARY OF THE INVENTION

Briefly, and in general terms, a solar cell according to an aspect of the present invention comprises a substrate; a first solar subcell composed of GeSiSn disposed over the substrate and having a first band gap; a second solar subcell composed of GaAs, InGaAsP, or InGaP and disposed over the first solar subcell having a second band gap greater than the first band gap and lattice matched to said first solar subcell; and a third solar subcell composed of GaInP and disposed over the second solar subcell having a third band gap greater than the second band gap and lattice matched with respect to the second subcell.

In another aspect, a solar cell according to an aspect of the present invention comprises a bottom solar subcell composed of GeSiSn having a first band gap in the range of 0.7 to 1.2 eV; one or more middle solar subcells disposed over the bottom solar subcell, each having a band gap greater than the first band gap and in the range of 1.0 to 2.4 eV, and lattice matched to said bottom solar subcell; and a top solar subcell disposed over the middle solar subcells and having a third band gap greater than the band gap of the uppermost middle solar subcell and in the range of 1.6 to 2.4 eV, and lattice matched with respect to the middle subcells.

In another aspect, a solar cell according to an aspect of the present invention comprises a bottom solar subcell composed of GeSiSn having a first band gap in the range of 0.7 to 1.2 eV; one or more middle solar subcells disposed over the bottom solar subcell, each having a band gap greater than the first band gap and in the range of 1.0 to 2.4 eV, and lattice matched to said bottom solar subcell; and a top solar subcell disposed over the middle solar subcells and having a third band gap greater than the band gap of the uppermost middle solar subcell and in the range of 1.6 to 2.4 eV, and lattice matched with respect to the middle subcells.

Some implementations of the present invention may incorporate or implement fewer of the aspects and features noted in the foregoing summaries.

Additional aspects, advantages, and novel features of the present invention will become apparent to those skilled in the art from this disclosure, including the following detailed description as well as by practice of the invention. While the invention is described below with reference to preferred embodiments, it should be understood that the invention is not limited thereto. Those of ordinary skill in the art having access to the teachings herein will recognize additional applications, modifications and embodiments in other fields, which are within the scope of the invention as disclosed and claimed herein and with respect to which the invention could be of utility.

### BRIEF DESCRIPTION OF THE DRAWINGS

The invention will be better and more fully appreciated by reference to the following detailed description when considered in conjunction with the accompanying drawings, wherein:

FIG. 1 is a graph representing the bandgap of certain binary materials and their lattice constants;

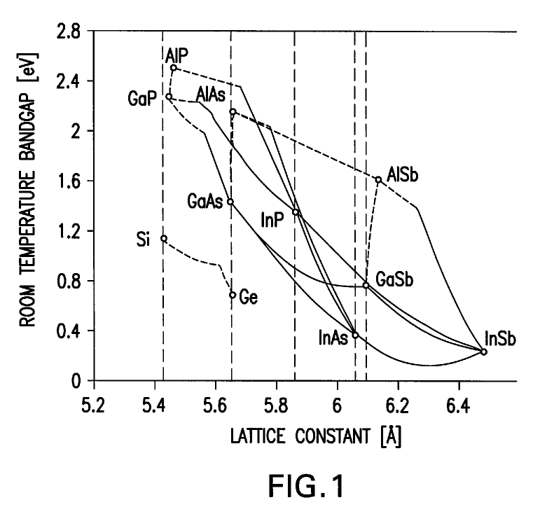

FIG. 2 is a cross-sectional view of the solar cell of the invention after the deposition of semiconductor layers on the growth substrate according to one embodiment of the present invention;

FIG. 3 is a highly simplified cross-sectional view of the solar cell of FIG. 2 after the next process step;

FIG. 4 is a cross-sectional view of the solar cell of FIG. 3 after the next process step;

FIG. 5 is a cross-sectional view of the solar cell of FIG. 4 after the next process step;

FIG. 6A is a top plan view of a wafer in which four solar cells are fabricated;

FIG. 6B is a bottom plan view of the wafer of FIG. 6A;

FIG. 6C is a top plan view of a wafer in which two solar cells are fabricated;

FIG. 7 is a cross-sectional view of the solar cell of FIG. 5 after the next process step;

FIG. 8 is a cross-sectional view of the solar cell of FIG. 7 after the next process step in which a cover glass is attached; and

FIG. 9 is a graph of the doping profile in the base and emitter layers of a subcell in the solar cell according to the present invention.

### DESCRIPTION OF THE PREFERRED EMBODIMENT

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

The basic concept of fabricating a multijunction solar cell is to grow the subcells of the solar cell on a substrate in an ordered sequence. That is, the low band gap subcells (i.e. subcells with band gaps in the range of 0.7 to 1.2 eV), are grown epitaxially directly on a semiconductor growth substrate, such as for example GaAs or Ge, and such subcells are consequently lattice matched to such substrate. One or more intermediate band gap middle subcells (i.e. with band gaps in the range of 1.0 to 2.4 eV) can then be grown on the low band gap subcell.

A top or upper subcell is formed over the middle subcell such that the top subcell is substantially lattice matched with respect to the middle subcell and such that the top subcell has a third higher band gap (i.e., a band gap in the range of 1.6 to 2.4 eV).

A variety of different features and aspects of multijunction solar cells are disclosed in the related applications noted above. Some or all of such features may be included in the structures and processes associated with the solar cells of the present invention.

The lattice constants and electrical properties of the layers in the semiconductor structure are preferably controlled by specification of appropriate reactor growth temperatures and times, and by use of appropriate chemical composition and dopants. The use of a vapor deposition method, such as Organo Metallic Vapor Phase Epitaxy (OMVPE), Metal Organic Chemical Vapor Deposition (MOCVD), or other vapor deposition methods, or other deposition techniques, such as Molecular Beam Epitaxy (MBE), for the reverse growth may enable the layers in the monolithic semiconductor structure forming the cell to be grown with the required thickness, elemental composition, dopant concentration and grading and conductivity type.

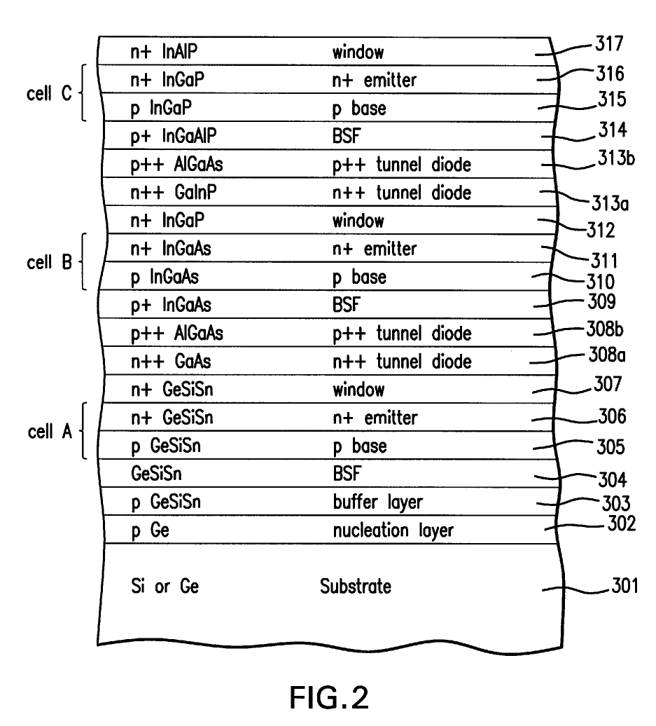

FIG. 2 depicts the multijunction solar cell according to the present invention after the sequential formation of the three subcells A, B and C on a silicon or germanium growth substrate. More particularly, there is shown a substrate 301, which is preferably silicon (Si), but may also be germanium (Ge) or other suitable material.

In the case of a Ge substrate, a nucleation layer 302 is deposited directly on the substrate 301. On the substrate 301, or over the nucleation layer 302 (in the case of a Ge substrate), a buffer layer 303 is further deposited. In the case of Ge substrate, the buffer layer 303 is preferably p type GeSiSn. A BSF layer 304 of p+ type GeSiSn is then deposited on layer 303. The subcell A, consisting of a p type base layer 305 and a n+ type emitter layer 306, is then epitaxially deposited on the BSF layer 304. The subcell A is generally latticed matched to the growth substrate 301. Subcell A may have a band gap of approximately 0.9 eV.

The BSF layer 304 drives minority carriers from the region near the base/BSF interface surface to minimize the effect of recombination loss. In other words, a BSF layer 304 reduces recombination loss at the backside of the solar subcell A and thereby reduces the recombination in the base.

It should be noted that the multijunction solar cell structure could be formed by any suitable combination of group III to V elements listed in the periodic table subject to lattice constant and bandgap requirements, wherein the group III includes boron (B), aluminum (Al), gallium (Ga), indium (In), and thallium (T). The group IV includes carbon (C), silicon (Si), germanium (Ge), and tin (Sn). The group V includes nitrogen (N), phosphorus (P), arsenic (As), antimony (Sb), and bismuth (Bi).

On top of the base layer 306 a window layer 307, preferably n+ type GeSiSn, is deposited, and used to reduce recombination loss.

On top of the window layer 307 is deposited a sequence of heavily doped p-type and n-type layers 308a and 308b that form a tunnel diode, i.e. an ohmic circuit element that connects subcell A to subcell B. Layer 308a is preferably composed of n++ GaAs, and layer 308b is preferably composed of p++ AlGaAs.

On top of the tunnel diode layers 308a/308b a BSF layer 309 is deposited, preferably p+ type InGaAs. More generally, the BSF layer 309 used in the subcell B operates to reduce the interface recombination loss. It should be apparent to one skilled in the art, that additional layer(s) may be added or deleted in the cell structure without departing from the scope of the present invention.

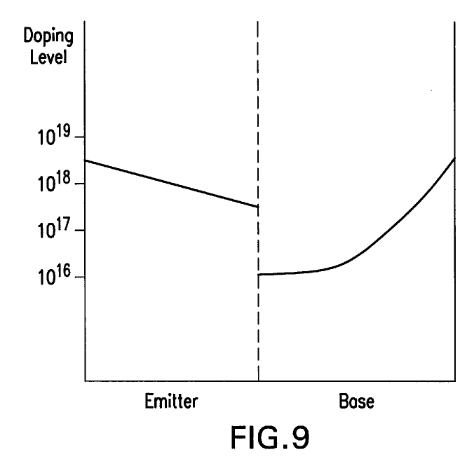

On top of the BSF layer 309, the layers of subcell B are deposited: the p type base layer 310 and the n+ type emitter layer 311. These layers are preferably composed of InGaAs, although any other suitable materials consistent with lattice constant and bandgap requirements may be used as well. Thus, subcell B may be composed of a GaAs, GaInP, GaInAs, GaAsSb, or GaInAsN emitter region and a GaAs, GaInAs, GaAsSb, or GaInAsN base region. The band gap of subcell B may be approximately 1.35 eV. The doping profile of layers 310 and 311 according to the present invention will be discussed in conjunction with FIG. 9.

On top of the subcell B is deposited a window layer 312 which performs the same function as the window layer 307. The p++/n++ tunnel diode layers 313a and 313b respectively are deposited over the window layer 312, similar to the layers 308a and 308b, forming an ohmic circuit element to connect subcell B to subcell C. The layer 313a is preferably composed of n++GaInP, and layer 313b is preferably composed of p++AlGaAs.

A BSF layer 314, preferably composed of p+ type InGaAlP, is then deposited over the tunnel diode layer 313b. This BSF layer operates to reduce the recombination loss in subcell “C”. It should be apparent to one skilled in the art that additional layers may be added or deleted in the cell structure without departing from the scope of the present invention.

On top of the BSF layer 314 the layers of subcell C are deposited: the p type base layer 315 and the n+ type emitter layer 316. These layers are preferably composed of p type InGaP and n+ type InGaP, respectively, although any other suitable materials consistent with lattice constant and bandgap requirements may be used as well. The band gap of subcell C may be approximately 1.75 eV. The doping profile of layers 315 and 316 according to the present invention will be discussed in conjunction with FIG. 9.

A window layer 317, preferably composed of n+ type InAlP is then deposited on top of the subcell C, the window layer performing the same function as the window layers 307 and 312.

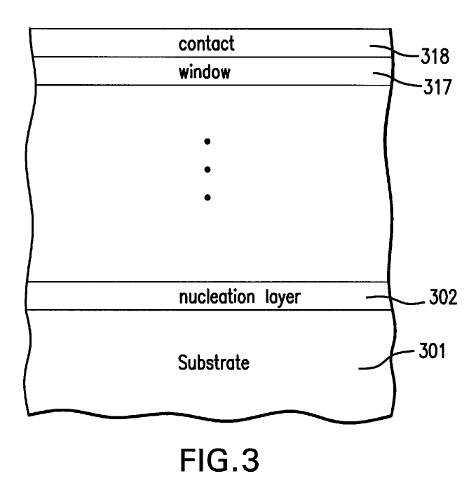

FIG. 3 is a highly simplified cross-section view of the solar cell of FIG. 2 which shows the next process step in which a high band gap contact layer 318, preferably composed of n+ type InGaAs, is deposited on the window layer 317.

It should be apparent to one skilled in the art, that additional layer(s) may be added or deleted in the cell structure without departing from the scope of the present invention.

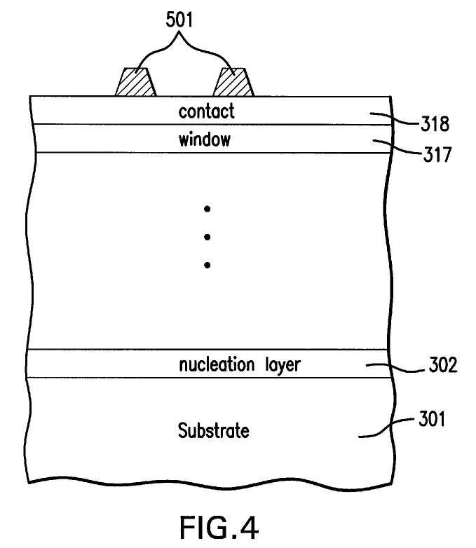

FIG. 4 is a cross-sectional view of the solar cell of FIG. 3 after the next sequence of process steps in which a photoresist layer (not shown) is placed over the semiconductor contact layer 318. The photoresist layer is lithographically patterned with a mask to form the locations of the grid lines 501, portions of the photoresist layer where the grid lines are to be formed are removed, and a metal contact layer 319 is then deposited by evaporation or similar processes over both the photoresist layer and into the openings in the photoresist layer where the grid lines are to be formed. The photoresist layer portion covering the contact layer 318 is then lifted off to leave the finished metal grid lines 501, as depicted in the Figures.

The grid lines 501 are preferably composed of the sequence of layers Pd/Ge/Ti/Pd/Au, although other suitable sequences and materials may be used as well.

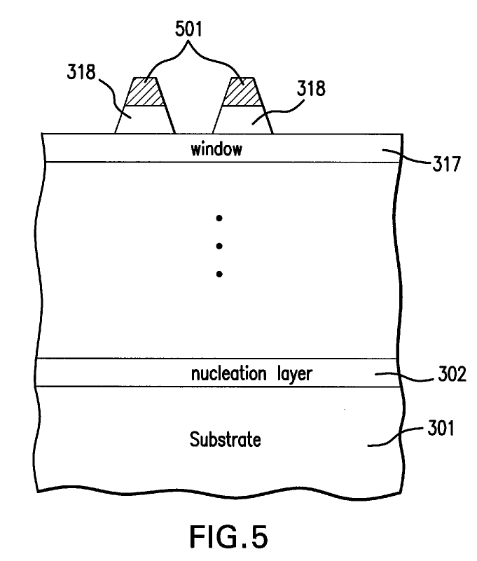

FIG. 5 is a cross-sectional view of the solar cell of FIG. 4B after the next process step in which the grid lines are used as a mask to etch down the surface to the window layer 317 using a citric acid/peroxide etching mixture.

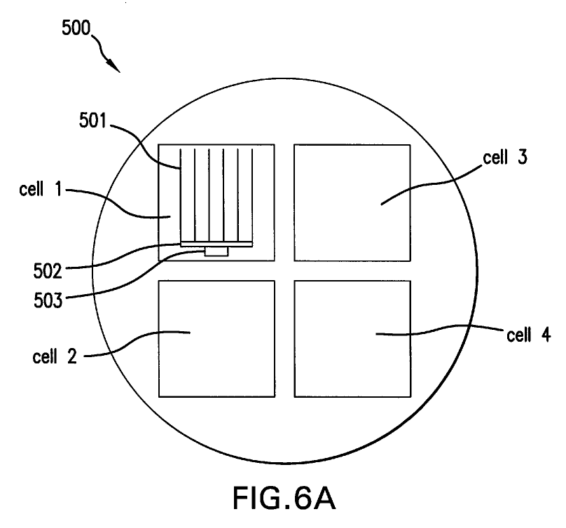

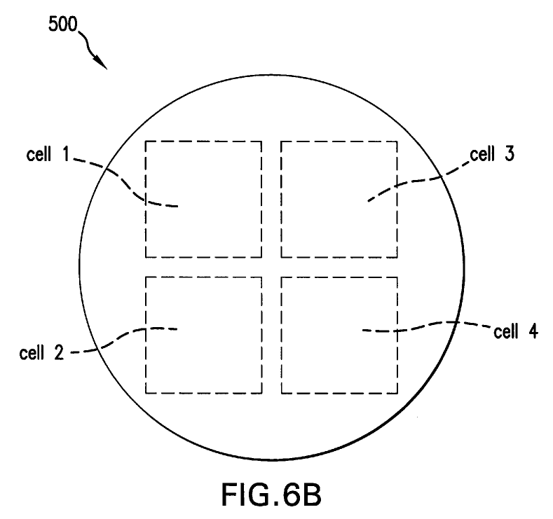

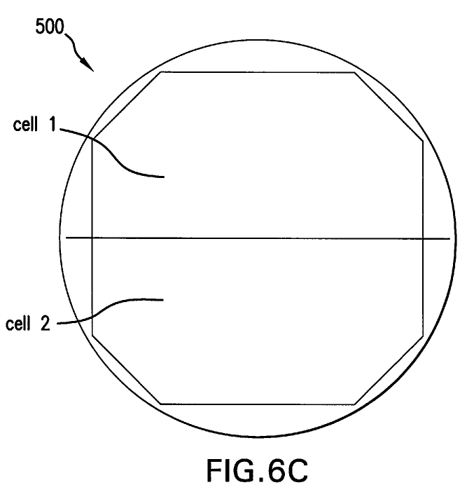

FIG. 6A is a top plan view of a 100 mm (or 4 inch) wafer in which four solar cells are implemented. The depiction of four cells is for illustration for purposes only, and the present invention is not limited to any specific number of cells per wafer.

In each cell there are grid lines 501 (more particularly shown in cross-section in FIG. 5), an interconnecting bus line 502, and a contact pad 503. The geometry and number of grid and bus lines and contact pads are illustrative, and the present invention is not limited to the illustrated embodiment.

FIG. 6B is a bottom plan view of the wafer of FIG. 6A, showing in outline the position of the four solar cells.

FIG. 6C is a top plan view of a 100 mm (or 4 inch) wafer in which two solar cells are implemented. Each solar cell has an area of 26.3 cm².

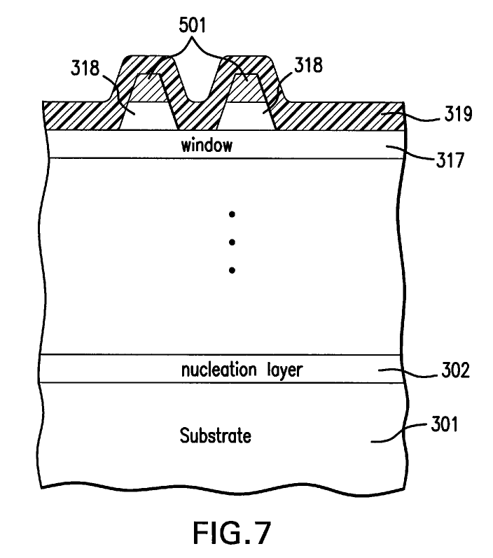

FIG. 7 is a cross-sectional view of the solar cell of FIG. 5 after the next process step in which an antireflective (ARC) dielectric coating layer is applied over the entire surface of the top side of the wafer with the grid lines 501.

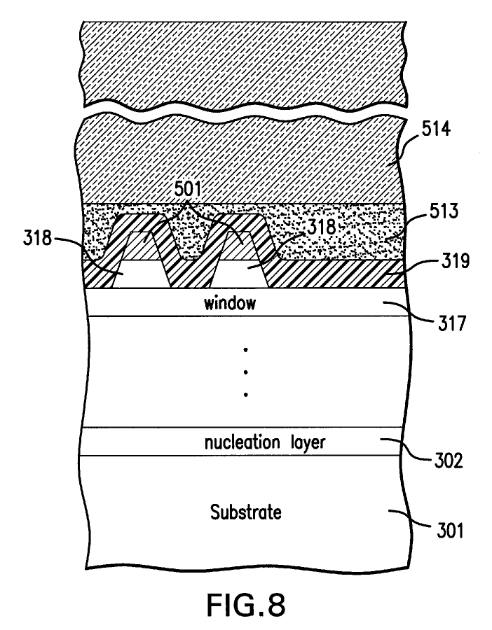

FIG. 8 is a cross-sectional view of the solar cell of FIG. 7 after the next process step in a second embodiment of the present invention in which a cover glass 514 is secured to the top of the cell by an adhesive 513. The cover glass 514 is typically about 4 mils thick and preferably covers the entire channel 510, extends over a portion of the mesa 516, but does not extend to channel 511. Although the use of a cover glass is desirable for many environmental conditions and applications, it is not necessary for all implementations, and additional layers or structures may also be utilized for providing additional support or environmental protection to the solar cell.

FIG. 9 is a graph of a doping profile in the emitter and base layers in one or more subcells of the multijunction solar cell of the present invention. The various doping profiles within the scope of the present invention, and the advantages of such doping profiles are more particularly described in copending U.S. patent application Ser. No. 11/956,069 filed Dec. 13, 2007, herein incorporated by reference. The doping profiles depicted herein are merely illustrative, and other more complex profiles may be utilized as would be apparent to those skilled in the art without departing from the scope of the present invention.

It will be understood that each of the elements described above, or two or more together, also may find a useful application in other types of constructions differing from the types of constructions described above.

In addition, although the illustrated embodiment is configured with top and bottom electrical contacts, the subcells may alternatively be contacted by means of metal contacts to laterally conductive semiconductor layers between the subcells. Such arrangements may be used to form 3-terminal, 4-terminal, and in general, n-terminal devices. The subcells can be interconnected in circuits using these additional terminals such that most of the available photogenerated current density in each subcell can be used effectively, leading to high efficiency for the multijunction cell, notwithstanding that the photogenerated current densities are typically different in the various subcells.

As noted above, the present invention may utilize an arrangement of one or more, or all, homojunction cells or subcells, i.e., a cell or subcell in which the p-n junction is formed between a p-type semiconductor and an n-type semiconductor both of which have the same chemical composition and the same band gap, differing only in the dopant species and types. Subcell C, with p-type and n-type InGaP is one example of a homojunction subcell. Alternatively, as more particularly described in U.S. Pat. No. 7,071,407, the present invention may utilize one or more, or all, heterojunction cells or subcells, i.e., a cell or subcell in which the p-n junction is formed between a p-type semiconductor and an n-type semiconductor having different chemical compositions of the semiconductor material in the n-type regions, and/or different band gap energies in the p-type regions, in addition to utilizing different dopant species and type in the p-type and n-type regions that form the p-n junction.

In some cells, a thin so-called “intrinsic layer” may be placed between the emitter layer and base layer, with the same or different composition from either the emitter or the base layer. The intrinsic layer may function to suppress minority-carrier recombination in the space-charge region. Similarly, either the base layer or the emitter layer may also be intrinsic or not-intentionally-doped (“NID”) over part or all of its thickness. Some such configurations are more particularly described in copending U.S. patent application Ser. No. 12/253,051, filed Oct. 16, 2008.

The composition of the window or BSF layers may utilize other semiconductor compounds, subject to lattice constant and band gap requirements, and may include AlInP, AlAs, AlP, AlGaInP, AlGaAsP, AlGaInAs, AlGaInPAs, GaInP, GaInAs, GaInPAs, AlGaAs, AlInAs, AlInPAs, GaAsSb, AlAsSb, GaAlAsSb, AlInSb, GaInSb, AlGaInSb, AlN, GaN, InN, GaInN, AlGaInN, GaInNAs, AlGaInNAs, ZnSSe, CdSSe, and similar materials, and still fall within the spirit of the present invention.

While the invention has been illustrated and described as embodied in a multijunction solar cell, it is not intended to be limited to the details shown, since various modifications and structural changes may be made without departing in any way from the spirit of the present invention.

Thus, while the description of this invention has focused primarily on solar cells or photovoltaic devices, persons skilled in the art know that other optoelectronic devices, such as thermophotovoltaic (TPV) cells, photodetectors and light-emitting diodes (LEDS) are very similar in structure, physics, and materials to photovoltaic devices with some minor variations in doping and the minority carrier lifetime. For example, photodetectors can be the same materials and structures as the photovoltaic devices described above, but perhaps more lightly-doped for sensitivity rather than power production. On the other hand LEDs can also be made with similar structures and materials, but perhaps more heavily-doped to shorten recombination time, thus radiative lifetime to produce light instead of power. Therefore, this invention also applies to photodetectors and LEDs with structures, compositions of matter, articles of manufacture, and improvements as described above for photovoltaic cells.

The foregoing described embodiments depict different components contained within, or connected with, different other components. It is to be understood that such depicted arrangements or architectures are merely exemplary, and that in fact many other arrangements or architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of specific structures, architectures or intermedial components. Likewise, any two components so associated can also be viewed as being “operably connected” or “operably coupled” to each other to achieve the desired functionality.

While particular embodiments of the present invention have been shown and described, it will be understood by those skilled in the art that, based upon the teachings herein, changes and modifications may be made without departing from this invention and its broader aspects and, therefore, the appended claims are to encompass within their scope all such changes and modifications as are within the true spirit and scope of this invention. Furthermore, it is to be understood that the invention is solely defined by the appended claims. It will be understood by those within the art that, in general, terms used herein, and especially in the appended claims (e.g., in the bodies of the appended claims) are generally intended as “open” terms (e.g., the term “including” should be interpreted as “including but not limited to,” the term “having” should be interpreted as “having at least,” the term “includes” should be interpreted as “includes but is not limited to,” “comprise” and variations thereof, such as, “comprises” and “comprising” are to be construed in an open, inclusive sense, that is as “including, but not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention and, therefore, such adaptations should and are intended to be comprehended within the meaning and range of equivalence of the following claims.

1. A multijunction solar cell comprising:
a substrate;
a first solar subcell composed of GeSiSn disposed over the substrate and having a first band gap;
a second solar subcell composed of GaAs, InGaAsP, or InGaP and disposed over the first solar subcell having a second band gap greater than the first band gap and lattice matched to said first solar subcell; and
a third solar subcell composed of GaInP and disposed over the second solar subcell having a third band gap greater than the second band gap and lattice matched with respect to the second subcell.

2. A solar cell as defined in claim 1, wherein the substrate is composed of silicon or germanium.

3. A solar cell as defined in claim 1, further comprising a GeSiSn buffer layer deposited over said substrate.

4. A solar cell as defined in claim 3, further comprising a GeSiSn BSF layer deposited over said buffer layer.

5. A solar cell as defined in claim 1, further comprising a GeSiSn window layer deposited over said first solar subcell.

6. A solar cell as defined in claim 1, further comprising a tunnel diode comprised of GaAs and AlGaAs disposed over said first solar subcell.

7. A solar cell as defined in claim 1, wherein said first solar subcell has a band gap of approximately 0.9 eV.

8. A solar cell as defined in claim 1, wherein said second solar subcell has a band gap of approximately 1.35 eV.

9. A solar cell as defined in claim 1, wherein said third solar subcell has a band gap of approximately 1.75 eV.

10. A multijunction solar cell comprising:
a bottom solar subcell composed of GeSiSn having a first band gap in the range of 0.7 to 1.2 eV;
one or more middle solar subcells disposed over the bottom solar subcell, each having a band gap greater than the first band gap and in the range of 1.0 to 2.4 eV, and lattice matched to said bottom solar subcell; and
a top solar subcell disposed over the middle solar subcells and having a third band gap greater than the band gap of the uppermost middle solar subcell and in the range of 1.6 to 2.4 eV, and lattice matched with respect to the middle subcells.

11. A solar cell as defined in claim 10, further comprising substrate composed of silicon or germanium, wherein the bottom subcell is disposed over and lattice matched to said substrate.

12. A solar cell as defined in claim 11, further comprising a GeSiSn buffer layer deposited over said substrate.

13. A solar cell as defined in claim 12, further comprising a GeSiSn BSF layer deposited over said buffer layer.
